(19) United States
(12) Patent Application Publication
(10) Pub. No.: US 2005/0179122 A1
(43) Pub. Date: Aug. 18, 2005

(54) IC card

(75) Inventors: Yoshihito Okawa, Tochigi (JP); Seiji Kanno, Tochigi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/060,373

(22) Filed: Feb. 17, 2005

(30) Foreign Application Priority Data
Feb. 17, 2004 (JP) P. 2004-040107

(51) Int. Cl. H01L 23/34

(52) U.S. Cl. 257/679; 257/724

(57) ABSTRACT

A reinforcing plate 11 is bonded to an IC chip 6 mounted on an IC module 2. Sealing resin 10 used for absorbing the impact on the IC chip 6 has the modulus of elasticity of 1 GPa or less and a thickness of 5 μm or more.

### BACKGROUND OF THE INVENTION

1. Field of the Invention

The present invention relates to a card having an IC module with a semiconductor chip serving as a memory, a CPU, or the like mounted thereon.

2. Description of the related art

Conventionally, various cards such as ID cards for identification, credit cards or the like are generally called magnetic cards in which a magnetic stripe for information storage is coated on a plastic plate having the same size as that of a business card. The magnetic card magnetically stores information, and thus the information may be easily deciphered by a third party. As a result, data may be easily forged and a forged card may be easily created.

Accordingly, in recent years, instead of the magnetic card, an IC card with a semiconductor chip (hereinafter, referred to as ‘IC chip’) serving as a memory, a CPU or the like mounted thereon has been developed. In such an IC card, encrypted data is stored, and thus security of individual information can be enhanced.

In an earlier IC card, a contact IC card in which data communication with a card reader is performed in a contact manner is widely used. In this case, however, the IC card is mechanically and electrically connected to the card reader, and thus electrostatic breakdown of an IC circuit or contact defect of a connection terminal may occur. Further, there is a problem in that the structure of the card reader is complicated. Therefore, at present, a large number of non-contact IC cards in which data communication with the card reader is performed in a non-contact manner has been developed.

The non-contact IC card is generally manufactured through the following process.

(1) In order to form an antenna circuit, printing is performed on a sheet in which a metal leaf such as aluminum or copper is attached to a resin sheet. As for printing, offset printing, gravure printing, screen printing, or photographic printing may be used.

(2) After printing is performed to form the antenna circuit, etching is performed.

(3) An IC module with an IC chip as a bare chip mounted thereon is directly laminated on the antenna circuit formed by etching. An adhesive or an adhesive sheet is laminated on both surfaces of the IC module. Then, a resin sheet made of plastic is laminated outside.

(4) In the state of (3), heat melting is performed by a heat press to integrate them.

(5) Cutting is performed with a mold according to a predetermined size.

The non-contact IC card is manufactured in such a manner. In such a structure, however, the IC chip is generally vulnerable to external stress such as bending, pressure, or impact applied thereto, and then the IC chip is damaged to be disabled. In order to solve this problem, there is suggested a structure which the IC chip is resistant to external stress (for example, see Japanese Patent Laid-Open No. 9-156265 (P. 3 and FIG. 1), Japanese Patent Laid-Open No. 9-263082 (P. 3 and FIG. 2), or Japanese Patent Laid-Open No. 2000-182016 (P. 4 and FIG. 1)).

In Japanese Patent Laid-Open No. 9-156265 (P. 3 and FIG. 1), an IC card in which the IC chip is mounted on a circuit board, a spacer provided with a hollowed hole for housing the IC chip is adhered to the circuit board, a stainless plate which has a thickness of about 30 μm and is larger than the hollowed hole is arranged just above the IC chip and the spacer as a reinforcing plate, and a cover film is adhered to the stainless plate is disclosed.

In Japanese Patent Laid-Open No. 9-263082 (P. 3 and FIG. 2), an IC card in which a stainless plate having a thickness of about 20 μm is adhered to at least one surface of the IC chip as a reinforcing plate, the IC chip is buried into a sheet-shaped intermediate layer, and sheets are adhered to both surfaces of the intermediate layer is disclosed. In Patent Document 3, an IC card in which relationship between the thickness of a reinforcing plate and the thickness of the IC chip is in a predetermined range is disclosed.

When the IC card is used, for example, it is expected that various stress such as ‘bending stress’ and ‘torsional stress’ applied to the IC card when a person takes a seat with keeping the IC card in a back pocket of a pants, ‘point-pressure stress’ applied to the IC card when a relatively acute projection such as the tip of a ballpoint pen presses the IC card, ‘impact stress’ applied to the IC card when an article falls, or the like occur. Further, stress may be applied to the front surface or the back surface of the IC card.

The reinforcing means disclosed in the above-described Patent Documents 1 to 3 can ensure the strength to ‘bending stress’, ‘torsional stress’, and ‘point-pressure stress’ in the expected environment of use. However, the strength to ‘impact stress’ cannot be ensured with the reinforcing means.

The present invention has been made in consideration of the above-described problem, and it is an object of the present invention to provide an IC card which ensures the strength to ‘bending stress’, ‘torsional stress’, and ‘point-pressure stress’, and is resistant to ‘impact stress’.

The above-described objects are achieved by the following configuration or method.

(1) An IC module for an IC card comprises a film-shaped base substrate, an antenna circuit formed on the base substrate, a semiconductor chip mounted on the antenna circuit, a reinforcing plate arranged above the semiconductor chip, and a sealing resin substantially covering an entire region of the semiconductor chip to bond the reinforcing plate to the semiconductor chip. Here, the sealing resin has the modulus of elasticity of 1 GPa (1 GPa=1×10⁹ Pa) or less.

(2) In the IC module described in (1), the reinforcing plate may be formed wider than an upper surface of the semiconductor chip.

(3) In the IC module described in (1) or (2), the sealing resin may be formed such that the sealing amount thereof extends over a projected area of the reinforcing plate, and the thickness thereof between the semiconductor chip and the reinforcing plate is 5 μm or more.

(4) An IC card comprises an IC module as described in any one of (1) to (3), and a protective member for protecting the IC module.

In the IC module described in (1), hardness of the sealing resin is defined, and thus the strength to ‘impact stress’ in the environment of use can be ensured. Accordingly, an IC card that ensures the strength to ‘bending stress’, ‘torsional stress’, and ‘point-pressure stress’, and is resistant to ‘impact stress’ can be provided.

In the IC module described in (2), the reinforcing plate has the size to cover the semiconductor chip, and thus the semiconductor chip can be reliably protected.

In the IC module described in (3), in addition to hardness of the sealing resin, the amount and the thickness of the sealing resin are defined, and thus the mechanical strength to ‘impact stress’ in the environment of use can be reliably ensured.

The IC card described in (4) comprises the IC module as described in any one of (1) to (3). Thus, an IC card which ensures the mechanical strength to ‘bending stress’, ‘torsional stress’, and ‘point-pressure stress’, and is resistant to ‘impact stress’ can be manufactured.

### BRIEF DESCRIPTION OF THE DRAWINGS

FIG. 1 is a cross-sectional view showing an IC card according to an embodiment of the present invention.

FIG. 2 is an expanded cross-sectional view showing essential parts around an IC chip of an IC module constituting the IC card shown in FIG. 1.

FIG. 3 is a diagram showing a process of forming an adhesive in manufacturing the IC card shown in FIG. 1.

FIG. 4 is a diagram for explaining a falling impact test of the IC card.

FIG. 5 is a diagram for explaining a point-pressure load test of the IC card.

FIG. 6 is a diagram showing relationship between the modulus of elasticity and the strength of sealing resin in the falling impact test of the IC card.

FIG. 7 is a diagram showing relationship between the thickness and the strength of the sealing resin in the falling impact test of the IC card.

FIG. 8 is a diagram showing relationship between the modulus of elasticity and the strength of the sealing resin in the point-pressure load test of the IC card.

### DESCRIPTION OF THE PREFERRED EMBODIMENTS

Hereinafter, a preferred embodiment for carrying out the present invention will be described in detail with reference to the drawings.

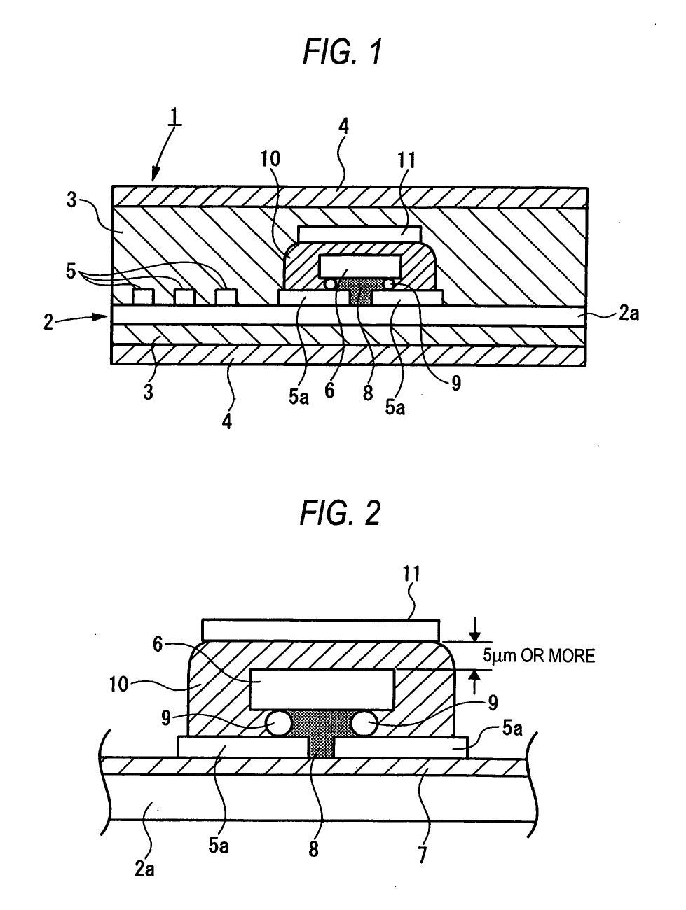

FIG. 1 is a cross-sectional view showing an IC card according to an embodiment of the present invention. Further, FIG. 2 is an expanded cross-sectional view showing essential parts around an IC chip of an IC module constituting the IC card shown in FIG. 1.

The IC card 1 of this embodiment has an IC module 2, and intermediate adhesive layers 3 and surface laminate layers 4 arranged on both surfaces the IC module 2 with the IC module 2 interposed therebetween.

The IC module 2 mainly has a sheet-shaped base substrate 2a made of resin, an antenna circuit 5, and an IC chip 6. Moreover, as the base substrate 2a, for example, a sheet made of resin, such as PET (polyester terephthalate), PEN (polyethylene naphthalate), PI (sheet made of polyimide) or the like, may be used.

The antenna circuit 5 is formed by arranging a metal sheet such as aluminum, copper, or the like on one surface (or both surfaces) of the base substrate 2a constituting the IC module 2 in a coil shape. Moreover, the intermediate adhesive layers 3 and the surface laminate layers 4 serve as a protective member for protecting the IC module 2 described in the present specification.

Specifically, the antenna circuit 5 is formed by bonding the metal sheet such as aluminum, copper or the like to the above-described sheet-shaped base substrate 2a made of resin with an adhesive sheet 7 (see FIG. 2), performing resist printing with a known printing method such as offset printing, gravure printing, screen printing, or photographic printing, and performing etching. Moreover, the antenna circuit 5 may be formed by performing screen printing with conductive paste. Further, the antenna circuit 5 may be formed with a combination of this method and the above-described method.

The antenna circuit 5 manufactured in such a manner is used as an antenna which communicates signals with an external apparatus such as a card reader or the like and as a receiving means which receives power for operating the IC chip 6 from the external apparatus such as the card reader or the like. Specifically, power is induced in a coil unit by electromagnetic waves sent from the external apparatus such as the card reader or the like, and the induced power is used as driving power of the IC chip 6 mounted on the antenna circuit 5. Further, the antenna circuit 5 is also used as electrode pads 5a for mounting the IC chip 6 thereon.

The IC chip 6 is bonded to the electrode pads 5a of the antenna circuit 5 with a chip bonding adhesive 8.

The chip bonding adhesive 8 is coated on the base substrate 2a of the IC module 2 in a paste state by a dispenser (not shown) or with the printing method. Alternatively, the chip bonding adhesive 8 having a sheet shape is mounted on the base substrate 2a of the IC module 2 to mount the IC chip 6 on the IC module 2.

The IC chip 6 is bonded to the electrode pads 5a of the antenna circuit 5 via bumps 9. Such a mounting method of the IC chip 6 is called a flip chip method.

Further, the approximately entire region of the IC chip 6 is covered with an impact-absorbing resin material 10 (hereinafter, referred to as a sealing resin).

The sealing resin 10 is an adhesive having a property of a low hardness value when being completely hardened and the modulus of elasticity of 1 GPa or less. The sealing resin 10 is used for absorbing the impact on the IC chip 6 and for bonding the reinforcing plate 11 arranged just above the IC chip 6 to the IC chip 6.

The use amount of the sealing resin 10, that is, the sealing amount of the sealing resin 10 on the IC chip 6 extends over the projected area of the reinforcing plate 11. Further, the thickness of the sealing resin 10 between the IC chip 6 and the reinforcing plate 11 is set to 5 μm or more.

Moreover, in order to suppress influence by external stress to the minimum (that is, in order to prevent microcracks on a chip surface and a dicing cut surface from occurring), as for the IC chip 6, one suffered from etching is preferably used.

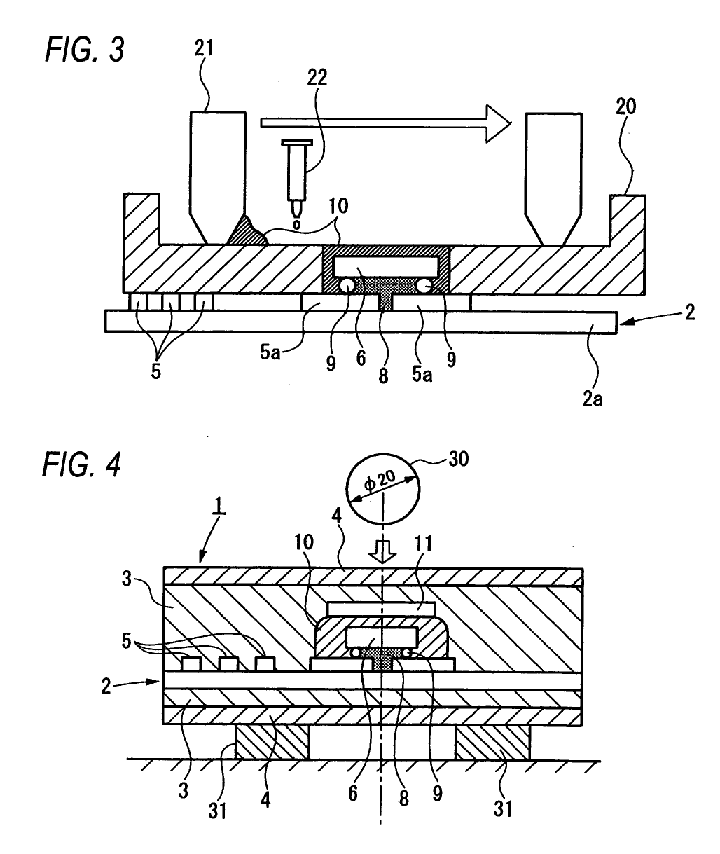

The formation of the sealing resin 10 is as shown in FIG. 3.

(1) First, on the approximately entire region including the upper side of the IC module 2 with the IC chip 6 mounted thereon, an adhesive coating mask 20 having a hole whose shape is adjusted according to the coated area and thickness of the sealing resin 10 is provided.

(2) After the adhesive coating mask 20 is provided, the sealing resin 10 is coated on the adhesive coating mask 20 by the required amount with a dispenser 22.

(3) After the sealing resin 10 is coated, an adhesive squeegee 21 is pulled to seal the sealing resin 10 around the IC chip 6.

(4) After the sealing resin 10 is sealed, the sealing resin 10 is hardened according to a predetermined hardening temperature and time.

Returning to FIG. 1, the reinforcing plate 11 has a planar area wider than that of the upper surface of the IC chip 6. The reinforcing plate 11 is concentrically arranged with respect to the IC chip 6. As the reinforcing plate 11, in order to make it endure the collective load caused by a point pressure, a material having high strength (a metal material having the hardness value of 400 Hv to 600 Hv), for example, a stainless plate is used.

Each of the intermediate adhesive layers 3 has a function of bonding the IC module 2 and each of the surface laminate layer 4 to each other and is made of an adhesive sheet material having fluidity when being melted by heating, for example, a sheet of a hot melting adhesive.

As the surface laminate layer 4, a resin sheet made of a material such as PET, PET-G, vinyl chloride or the like is used. Moreover, as described above, the intermediate adhesive layers 3 and the surface laminate layers 4 correspond to the protective member for protecting the IC module 2.

In manufacturing the IC card 1 having such a structure, first, the intermediate adhesive layers 3 are formed on both surfaces of the resultant IC module 2 with the IC module 2 interposed therebetween, and then the surface laminate layers 4 are formed outside the intermediate adhesive layers 3, such that a five-layered structure is formed. Then, the intermediate adhesive layers 3 are fluidized by means of the heat press (not shown), and vacuumization, pressing, and heating are performed so as to make the thickness uniform to adhere the respective layers. Subsequently, the adhesive is solidified by cooling and cutting is performed with a mold according to a predetermined size. As a result, the IC card 1 is manufactured.

Next, various stress test results to the IC module 2 will be described.

As for the test, two tests of a falling impact test and a point-pressure load test are performed. As a result, relationship between the hardness and strength of the sealing resin 10 and relationship between the distance between the sealing resin 10 and the IC chip 6 and the strength of the sealing resin 10 are obtained.

(Falling Impact Test)

As shown in FIG. 4, the falling impact test is performed by allowing a steel ball 30 having a diameter of 20 mm to fall on the card surface of the IC card 1 loaded on a fixing jig 31, on which the IC chip 6 is mounted, or an opposite surface thereto with the center of the IC chip 6 as a target. In FIG. 4, a case in which the test is performed on the card surface on which the IC chip 6 is mounted is shown. When the test is performed on the opposite surface, the IC card 1 is reversed.

When such a falling impact test is performed, a falling height at which the IC chip 6 is not damaged is measured.

It can be expected that, as a condition of the IC card 1, the weight of the steel ball 30 and the falling height are needed to be set to 50 g and 20 cm, respectively, in the environment of use. As a condition of the IC module 2, it is necessary that the weight of the steel ball 30 is in a range of from 10 to 25 g and the falling height is in a range of from 5 to 15 cm.

(Point-Pressure Load Test)

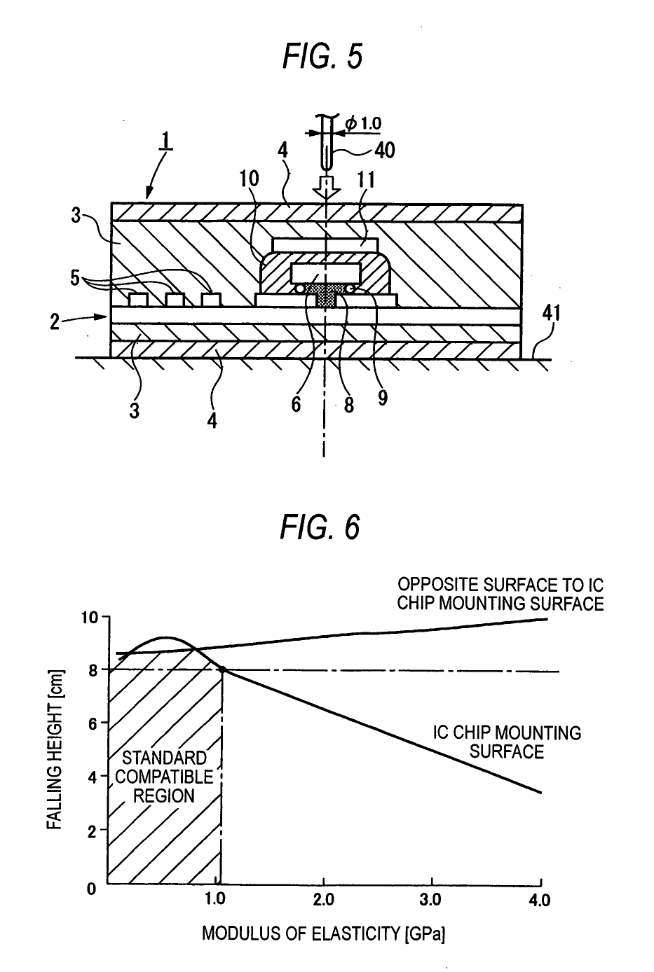

As shown in FIG. 5, the point-pressure load test is performed by applying the point-pressure load to the IC card surface on which the IC chip 6 of the IC module 2 is mounted or the opposite card surface thereto with a steel member 40 having a tip diameter of 1.0 mm for three seconds with the center of the IC chip 6 as a target. Moreover, on the opposite surface to the surface to which the load is applied, a fixing plate 41 made of a steel plate is provided. When such a point-pressure load test is performed, the point-pressure load at which the IC chip 6 is not damaged is measured. It is assumed that, as a condition of the IC card 1, the load of 6 kgf is needed to be applied in the environment of use. As a condition of the IC module 2, it is seen that that the load of 3 kgf is applied.

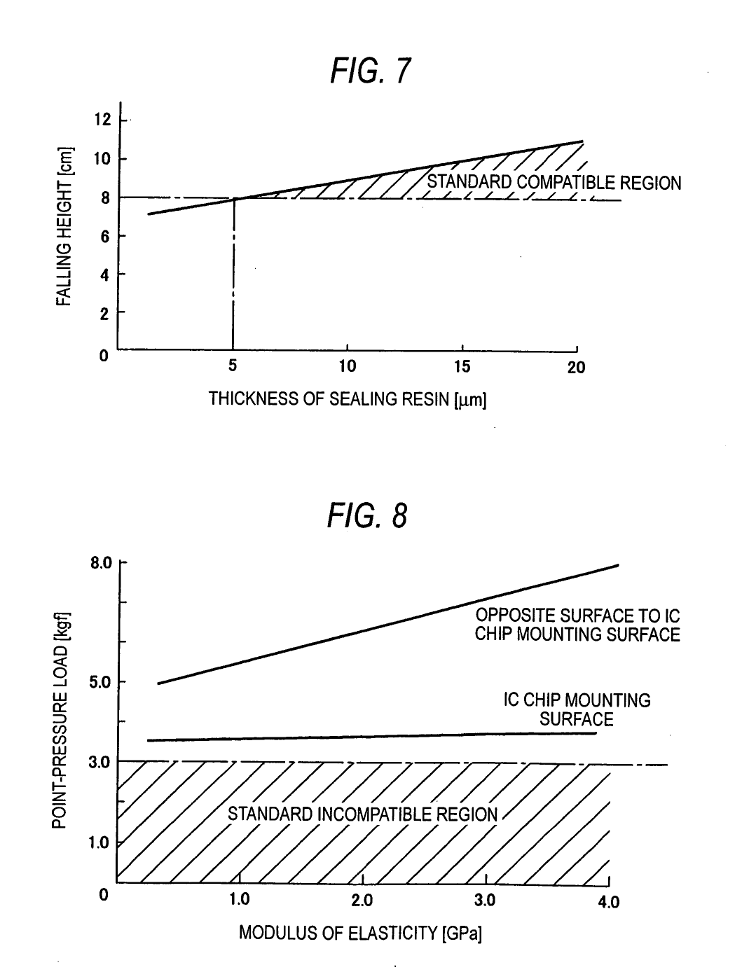

With the configuration of the IC module 2, when the modulus of elasticity, which is the hardness of the sealing resin 10, arbitrarily changes from 0.1 GPa to 4.0 GPa, the measurement result of the falling impact test on the mounting surface of the IC chip 6 and the opposite surface thereto is shown in FIGS. 6 and 7.

FIG. 6 shows relationship between the modulus of elasticity of the sealing resin 10 and the falling height of the steel ball 30.

As shown in FIG. 6, on the mounting surface of the IC chip 6, the falling height decreases starting from the modulus of elasticity of 1 GPa. To the contrary, on the opposite surface to the IC chip mounting surface, the falling height tends to increase as it goes toward an upper right-hand corner. Further, as for the hardness of the sealing resin 10 within the above-described range, the satisfactory strength can be ensured.

Therefore, it can be seen that, when paying attention to only the mounting surface of the IC chip 6, the hardness of the sealing resin 10, that is, the modulus of elasticity is needed to be set to 1 GPa or less. Moreover, a hatched region in FIG. 6 serves as a standard compatible region in which the hardness is 1 GPa or less.

FIG. 7 shows relationship regarding the distance between the IC chip 6 and the reinforcing plate 11, that is, the thickness of the sealing resin.

As seen from FIG. 7, in order to cope with the falling height of 8 cm of the steel ball 30, it is to be understood that the thickness of the sealing resin is needed to be 5 μm or more.

Next, with the configuration of the IC module 2, when the modulus of elasticity, which is the hardness of the sealing resin 10, arbitrarily changes from 0.1 GPa to 4.0 GPa, the measurement result of the point-pressure load test on the mounting surface of the IC chip 6 and the opposite surface thereto is shown in FIG. 8.

FIG. 8 shows relationship between the modulus of elasticity of the sealing resin 10 and the point-pressure load applied for three seconds. On the mounting surface of the IC chip 6, the change by the modulus of elasticity of the sealing resin 10 is not seen yet. To the contrary, on the opposite surface thereto, the point-pressure load tends to increase as it goes toward an upper right-hand corner. Thus, for the point-pressure load, the satisfactory strength can be ensured. Moreover, as for the point-pressure load, the influence by the thickness difference of the sealing resin is not seen so large.

Therefore, in order to satisfy the strength of both ‘impact stress’ and ‘point-pressure stress’, it can be seen that it is important to manage the hardness and the thickness of the sealing resin 10. Accordingly, it is to be understood that, preferably, the modulus of elasticity of the sealing resin 10 is set to 1 GPa or less and the distance between the IC chip 6 and the reinforcing plate 11 is set to 5 μm or more. Of course, the hardness and the thickness of the sealing resin 10 are not defined according to the set values of the sealing resin 10. For example, the hardness and the thickness of the sealing resin 10 may be defined according to correlation with the material or thickness of the reinforcing plate 11, or the thickness or hardness of the surface laminate layer 4.

As described above, according to the IC card 1 of the present embodiment, the reinforcing plate 11 is bonded to the IC chip 6 mounted on the IC module 2. Further, the sealing resin 10 used for absorbing the impact on the IC chip 6 has the modulus of elasticity of 1 GPa or less and the thickness of 5 μm or more. Thus, an IC card which can cope with ‘bending stress’, and ‘torsional stress’, and ‘point-pressure stress’, and is resistant to ‘impact stress’ can be obtained.

The present invention can be applied to an IC card with the IC module mounted thereon.

1. An integrated circuit (IC) module, comprising:
a film-shaped base substrate;
an antenna circuit, formed on the base substrate;
a semiconductor chip, mounted on the antenna circuit;
a reinforcing plate, arranged above the semiconductor chip; and
a sealing resin, substantially covering an entire region of the semiconductor chip to bond the reinforcing plate to the semiconductor chip,
wherein the sealing resin has the modulus of elasticity of 1 GPa or less.

2. The IC module according to claim 1,
wherein the reinforcing plate is formed wider than an upper surface of the semiconductor chip.

3. The IC module according to claim 1 or 2,
wherein the sealing resin is formed such that the sealing amount thereof extends over a projected area of the reinforcing plate; and
the thickness thereof between the semiconductor chip and the reinforcing plate is 5 μm or more.

4. An IC card comprising:
an IC module as claimed in any one of claims 1 to 3; and
a protective member for protecting the IC module.
